(19) United States
(12) Patent Application Publication
(10) Pub. No.: US 2024/0055552 A1
(43) Pub. Date: Feb. 15, 2024

(54) DISPLAY PANEL, PREPARATION METHOD THEREOF, AND DISPLAY DEVICE

(71) Applicant: Tianma Advanced Display Technology Institute (Xiamen) Co., Ltd., Xiamen (CN)

(72) Inventor: Sitao HUO, Xiamen (CN)

(73) Assignee: Tianma Advanced Display Technology Institute (Xiamen) Co., Ltd., Xiamen (CN)

(21) Appl. No.: 18/383,507

(22) Filed: Oct. 25, 2023

(30) Foreign Application Priority Data
Jun. 30, 2023 (CN) 202310798295.0

(51) Int. Cl. H01L 33/08; H01L 25/075; H01L 33/38; H01L 33/00

(52) U.S. Cl. CPC H01L 33/08; H01L 25/0753; H01L 33/38; H01L 33/0093; H01L 33/0095; H01L 2933/0033

(57) ABSTRACT

Provided are a display panel, a preparation method thereof, and a display device. The display panel includes a first substrate and light-emitting assemblies. The first substrate includes a plurality of signal lines. The light-emitting assemblies are located on a side of the first substrate. A light-emitting assembly includes a second substrate, a drive assembly, a light-emitting chip, and connection portions. The light-emitting chip is located on a side of the second substrate facing away from the first substrate. The drive assembly and the light-emitting chip are located on the same side of the second substrate. The drive assembly is configured to drive the light-emitting chip to emit light. The drive assembly is electrically connected to a signal line through the connection portion. The connection portion is at least partially located on a side of the second substrate facing the first substrate.

### CROSS-REFERENCE TO RELATED APPLICATION(S)

This application claims priority to Chinese Patent Application No. 202310798295.0 filed Jun. 30, 2023, the disclosure of which is incorporated herein by reference in its entirety.

### TECHNICAL FIELD

The present application relates to the field of display technology and, in particular, to a display panel, a preparation method thereof, and a display device.

### BACKGROUND

Micro light-emitting diode (Micro LED) is a new generation of display technology. Compared with the existing liquid crystal display, a micro LED has higher photoelectric efficiency, higher brightness, and a higher contrast ratio and can be combined with a flexible panel to implement a flexible display.

A light-emitting chip in a micro-LED display panel needs to be driven through array pixel circuits. However, the array pixel circuits occupy most of the region in the display panel, not helping improve the resolution of the micro-LED display panel. Therefore, a new display element is urgently needed.

### SUMMARY

Embodiments of the present application provide a display panel, a preparation method thereof, and a display device.

In one aspect, embodiments of the present application provide a display panel. The display panel includes a first substrate and light-emitting assemblies. The first substrate includes a plurality of signal lines. The light-emitting assemblies are located on a side of the first substrate. A light-emitting assembly of the light-emitting assemblies includes a second substrate, a drive assembly, a light-emitting chip, and a connection portion. The light-emitting chip is located on a side of the second substrate facing away from the first substrate. The drive assembly and the light-emitting chip are located on a same side of the second substrate. The drive assembly is configured to drive the light-emitting chip to emit light. The drive assembly is electrically connected to a signal line among the plurality of signal lines through the connection portion. The connection portion is at least partially located on a side of the second substrate facing the first substrate.

In another aspect, embodiments of the present application further provide a display device. The display device includes a display panel. The display panel includes a first substrate and light-emitting assemblies. The first substrate includes a plurality of signal lines. The light-emitting assemblies are located on a side of the first substrate. A light-emitting assembly of the light-emitting assemblies includes a second substrate, a drive assembly, a light-emitting chip, and a connection portion. The light-emitting chip is located on a side of the second substrate facing away from the first substrate. The drive assembly and the light-emitting chip are located on a same side of the second substrate. The drive assembly is configured to drive the light-emitting chip to emit light. The drive assembly is electrically connected to a signal line among the plurality of signal lines through the connection portion. The connection portion is at least partially located on a side of the second substrate facing the first substrate.

In another aspect, embodiments of the present application further provide a preparation method of a display panel. The method includes the steps below. A second substrate master is provided, and a plurality of drive assemblies are prepared on a first side of the second substrate master. A connection portion is prepared, where at least part of the connection portion is located on a second side of the second substrate master, and the second side is opposite to the first side. A light-emitting chip wafer comprising a plurality of light-emitting chips is provided.

The light-emitting chip wafer is aligned and bonded with the second substrate master to obtain a light-emitting assembly master. The light-emitting assembly master is cut to obtain a plurality of light-emitting assemblies. A first substrate is provided, where the first substrate includes a plurality of signal lines; and the plurality of light-emitting assemblies are transferred to the first substrate, where one of the plurality of light-emitting assemblies is electrically connected to one of the plurality of signal lines through the connection portion.

### BRIEF DESCRIPTION OF DRAWINGS

Features, advantages, and technical effects of example embodiments of the present application will be described below with reference to the drawings.

FIG. 1 is a top view illustrating the structure of a display panel according to some embodiments of the present application.

FIG. 2 is a sectional view illustrating the structure of a display panel according to some embodiments of the present application.

FIG. 3 is a sectional view illustrating the structure of another display panel according to some embodiments of the present application.

FIG. 4 is a sectional view illustrating the structure of another display panel according to some embodiments of the present application.

FIG. 5 is a top view illustrating the structure of another display panel according to some embodiments of the present application.

FIG. 6 is a sectional view taken along A-A of FIG. 5.

FIG. 7 is a top view illustrating the structure of another display panel according to some embodiments of the present application.

FIG. 8 is a sectional view taken along B-B′ of FIG. 7.

FIG. 9 is a sectional view illustrating the structure of another display panel according to some embodiments of the present application.

FIG. 10 is a top view illustrating the structure of a light-emitting assembly of a display panel according to some embodiments of the present application.

FIG. 11 is a top view illustrating the structure of a light-emitting assembly of another display panel according to some embodiments of the present application.

FIG. 12 is a sectional view illustrating the structure of another display panel according to some embodiments of the present application.

FIG. 13 is a sectional view illustrating the structure of another display panel according to some embodiments of the present application.

FIG. 14 is a top view illustrating the structure of a light-emitting assembly of another display panel according to some embodiments of the present application.

FIG. 15 is a sectional view illustrating the structure of another display panel according to some embodiments of the present application.

FIG. 16 is a top view illustrating the structure of a light-emitting assembly of another display panel according to some embodiments of the present application.

FIG. 17 is a top view illustrating the structure of a light-emitting assembly of another display panel according to some embodiments of the present application.

FIG. 18 is a top view illustrating the structure of another display panel according to some embodiments of the present application.

FIG. 19 is a top view illustrating the structure of another display panel according to some embodiments of the present application.

FIG. 20 is a top view illustrating the structure of another display panel according to some embodiments of the present application.

FIG. 21 is a top view illustrating the structure of another display panel according to some embodiments of the present application.

FIG. 22 is a top view illustrating the structure of another display panel according to some embodiments of the present application.

FIG. 23 is a sectional view illustrating the structure of another display panel according to some embodiments of the present application.

FIG. 24 is a sectional view illustrating the structure of another display panel according to some embodiments of the present application.

FIG. 25 is a sectional view illustrating the structure of another display panel according to some embodiments of the present application.

FIG. 26 is a top view illustrating the structure of a light-emitting assembly of another display panel according to some embodiments of the present application.

FIG. 27 is a top view illustrating the structure of another display panel according to some embodiments of the present application.

FIG. 28 is a top view illustrating the structure of a display device according to some embodiments of the present application.

FIG. 29 is a flowchart of a preparation method of a display panel according to an embodiment of the present application.

FIG. 30 is a diagram illustrating the process structure of the preparation method of a display panel according to an embodiment of the present application.

### DETAILED DESCRIPTION

Features and example embodiments in various aspects of the present invention are described hereinafter in detail. To provide a clearer understanding of the objects, technical solutions, and advantages of the present application, the present application is further described in detail in conjunction with drawings and embodiments. It is to be understood that the embodiments set forth below are intended to illustrate and not to limit the present application. To those skilled in the art, the present application may be implemented with no need for some of these specific details. The description of the embodiments hereinafter is intended only to provide a better understanding of the present application through examples of the present application.

It is to be noted that in this article, relationship terms such as a first and a second are used merely to distinguish one entity or operation from another. It does not necessarily require or imply any such actual relationship or order between these entities or operations. Furthermore, the term “comprising”, “including” or any other variant thereof is intended to encompass a non-exclusive inclusion so that a process, method, article, or device that includes a series of elements not only includes the expressly listed elements but may also include other elements that are not expressly listed or are inherent to such process, method, article, or device. In the absence of more restrictions, the elements defined by the statement “including . . . ” do not exclude the presence of additional identical elements in the process, method, article, or device that includes the elements.

Compared with an organic light-emitting display (OLED) and a thin-film transistor liquid crystal display (TFT-LCD), a micro-LED display panel has higher photoelectric efficiency, higher brightness, a higher contrast ratio, and lower power consumption.

However, light-emitting chips in the micro-LED display panel are driven through array pixel circuits to emit light. Moreover, a drive current is larger in the micro-LED display process, leading to higher sensitivity to the change of a current, requiring the arrangement of a more complicated circuit, and thereby limiting the development of the micro-LED display to high pixel per inch (PPI). The present application provides a display panel and a display device that can effectively improve the resolution of the display panel.

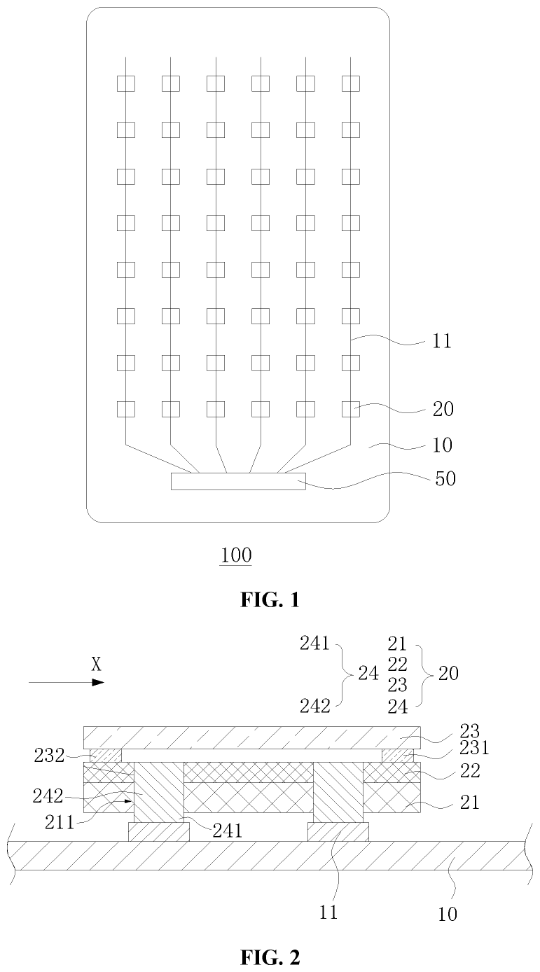

To better understand the present application, in one aspect, a display panel, a preparation method thereof, and a display device according to embodiments of the present application are described in detail hereinafter with reference to FIGS. 1 to 30.

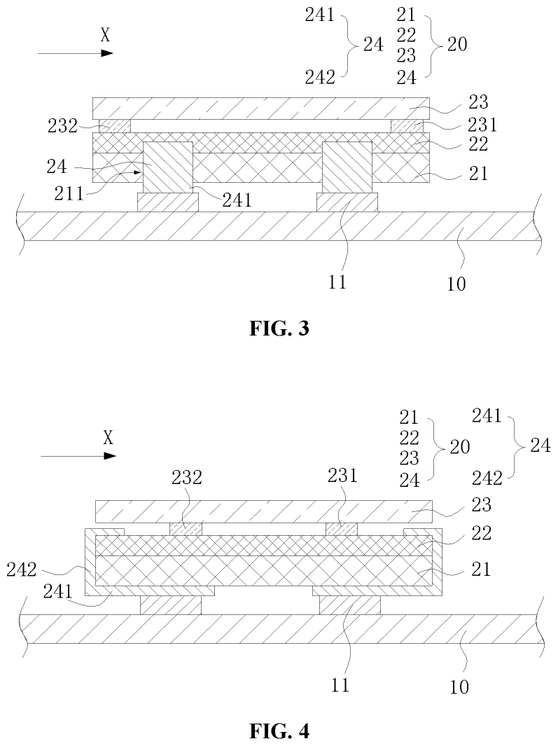

FIG. 1 is a top view illustrating the structure of a display panel according to some embodiments of the present application. FIG. 2 is a sectional view illustrating the structure of a display panel according to some embodiments of the present application.

As shown in FIGS. 1 and 2, embodiments of the present application provide a display panel 100. The display panel 100 includes a first substrate 10 and light-emitting assemblies 20. The first substrate 10 includes a plurality of signal lines 11. The light-emitting assemblies 20 are located on a side of the first substrate 10. A light-emitting assembly 20 includes a second substrate 21, a drive assembly 22, a light-emitting chip 23, and connection portions 24. The light-emitting chip 23 is located on a side of the second substrate 21 facing away from the first substrate 10. The drive assembly 22 and the light-emitting chip 23 are located on the same side of the second substrate 22. The drive assembly 22 is configured to drive the light-emitting chip 23 to emit light. The drive assembly 22 is electrically connected to a signal line 11 through a connection portion 24. The connection portion 24 is at least partially located on a side of the second substrate 21 facing the first substrate 10.

In an embodiment, the display panel 100 may be a transparent display panel or a non-transparent display panel. A transparent display panel includes a light-emitting region with a display function and a light-transmissive region allowing light to be transmitted. In other words, the transparent display panel may be used for image display. Moreover, a user may observe a background image behind the display panel 100 due to the existence of the light-transmissive region.

In an embodiment, the first substrate 10 includes a base, metal layers, and insulating layers between the metal layers. The metal layers and the insulating layers are located on a side of the base. The metal layers may include the signal lines 11. Of course, the metal layers may also include structures such as a capacitor or an electrode.

In an embodiment, the signal lines 11 may include a data signal line, a gating signal line, a power signal line, or other signal lines. The first substrate 10 may also include a control unit 50. The control unit 50 includes a driver chip. The driver chip is electrically connected to the light-emitting assemblies 20 through the signal lines 11.

In embodiments of the present application, multiple light-emitting assemblies 20 may be included. The light-emitting assemblies 20 may be arranged in array on the first substrate 10. Of course, the light-emitting assemblies 20 may also be arranged in other manners on the first substrate 10. The light-emitting assemblies 20 are located on a side of the first substrate 10. Exemplarily, by way of example, a surface of the first substrate 10 is a surface of the outermost layer among multiple layers carried on the base. The light-emitting assemblies 20 are located on a side of a surface insulating layer in the first substrate 10 facing away from the base. The surface insulating layer is provided with signal pins led out from the signal lines 11. The light-emitting assemblies 20 may be electrically connected to the signal pins. Of course, at least part of the signal lines 11 may be directly exposed on the surface of the first substrate 10. The light-emitting assemblies 20 may be electrically connected to the exposed signal lines 11 directly.

The light-emitting assembly 20 includes the second substrate 21, the drive assembly 22, the light-emitting chip 23, and the connection portions 24. The second substrate 21 may include the same layers as the first substrate 10. Exemplarily, the second substrate 21 includes a base, metal layers, and insulating layers between the metal layers. Alternatively, the second substrate 21 includes one or more of the three preceding types of layers. In some other examples, the light-emitting assembly 20 may be composed of a CMOS wafer and the light-emitting chip. The second substrate 21 and the drive assembly 22 form the CMOS wafer.

In an embodiment, the drive assembly 22 may include a semiconductor layer, metal layers, and insulating layers between the metal layers. The metal layers in the drive assembly 22 and the insulating layers in the drive assembly 22 for a circuit. Exemplarily, the formed circuit includes an array pixel circuit, a digital circuit, or other circuits. The circuit in the drive assembly 22 may be configured to drive the light-emitting chip 23 to emit light. Of course, the circuit in the drive assembly 22 may also be configured to control the light emission time and brightness of the light-emitting chip 23.

In embodiments of the present application, the drive assembly 22 and the light-emitting chip 23 are located on the same side of the second substrate 21 and each located on a side of the second substrate 21 facing away from the first substrate 10. In other words, the drive assembly 22 and the light-emitting chip 23 may be disposed side by side or may be stacked on a surface of the second substrate 21 facing away from the first substrate 10. Exemplarily, the drive assembly 22 is located between the light-emitting chip 23 and the second substrate 21. Alternatively, the light-emitting chip 23 is located between the drive assembly 22 and the second substrate 21. For ease of understanding, an example in which the drive assembly 22 is located between the light-emitting chip 23 and the second substrate 21 is taken for description in embodiments of the present application.

In an embodiment, the light-emitting chip 23 may include a micro LED, a mini LED, or other light-emitting elements. Light-emitting chips 23 in different light-emitting assemblies 20 may include one or more colors.

The drive assembly 22 is electrically connected to the signal line 11 through the connection portion 24. The connection portion 24 is at least partially located on a side of the second substrate 21 facing the first substrate 10. In other words, one end of the connection portion 24 is electrically connected to the drive assembly 22, and the other end of the connection portion 24 is electrically connected to the signal line 11 on the first substrate 10. Moreover, at least part of the connection portion 24 is located on a side of the second substrate 21 facing the first substrate 10 to simplify the mounting processing of disposing the light-emitting assembly 20 on the first substrate 10. A partial structure of the connection portion 24 is located on a side of the second substrate 21 facing the first substrate 10 to be configured to be electrically connected to the signal line 11. A partial structure of the connection portion 24 is located on a side of the second substrate 21 facing away from the first substrate 10 to be configured to be electrically connected to the drive assembly 22.

According to the display panel 100 provided in the present application, the display panel 100 includes the first substrate 10 and the light-emitting assemblies 20. The light-emitting assembly 20 includes the second substrate 21, the drive assembly 22, the light-emitting chip 23, and the connection portions 24. The drive assembly 22 may be configured to drive the light-emitting chip 23 to emit light. Therefore, the wiring on the first substrate 10 is reduced, thereby reducing the area occupied by a driver circuit in the display panel 100, reducing the limit of the driver circuit to the arrangement number of light-emitting chips 23, increasing the resolution of the display panel 100, reducing the overall size of the display panel 100, and helping with the miniaturization of the display panel 100.

FIG. 3 is a sectional view illustrating the structure of another display panel according to some embodiments of the present application. FIG. 4 is a sectional view illustrating the structure of another display panel according to some embodiments of the present application.

As shown in FIGS. 2 to 4, in some optional embodiments, the second substrate 21 includes hole structures 211 penetrating the second substrate 21. The connection portion 24 includes a first portion 241 located on a side of the second substrate 21 facing the first substrate 10 and a second portion 242 overlapping a hole structure 211 in a first direction X. The first direction X is parallel to a plane where the second substrate 21 is located.

In embodiments of the present application, the preceding arrangement helps implement the connection between the drive assembly 22 and the signal line 11, simplifies the structure of the connection portion 24, and reduces the preparation cost of the light-emitting assembly 20

In an embodiment, one or more hole structures 211 may be included.

In an embodiment, the hole structure 211 may also extend to a preset position of the drive assembly 22. Exemplarily, as shown in FIG. 2, the drive assembly 22 includes through holes. A through hole overlaps the hole structure 211. The connection portion 24 may connect a surface circuit of the drive assembly 22 facing the light-emitting chip 23 to the signal line 11 on the first substrate 10 through the through hole and the hole structure 211. Alternatively, as shown in FIG. 3, the drive assembly 22 includes blind holes. A blind hole overlaps the hole structure 211. The connection portion 24 may connect an internal circuit in the drive assembly 22 to the signal line 11 on the first substrate 10 through the blind hole and the hole structure.

In some optional embodiments, a hole (through hole or blind hole) in the drive assembly 20 may not overlap the hole structure 211 in the second substrate 21.

In an embodiment, the second portion 242 of the connection portion 24 may be located in the hole structure 211. Of course, as shown in FIG. 4, the second portion 242 of the connection portion 24 may also extend from a sidewall of the second substrate 21 in the thickness direction of the second substrate 21. It is to be understood that one end of the second portion 242 of the connection portion 24 facing away from the first portion 241 is electrically connected to the drive assembly 22. In other words, the second portion 242 extends from a side of the second substrate 21 facing away from the first substrate 10 to a side of the second substrate 21 facing the first substrate 10.

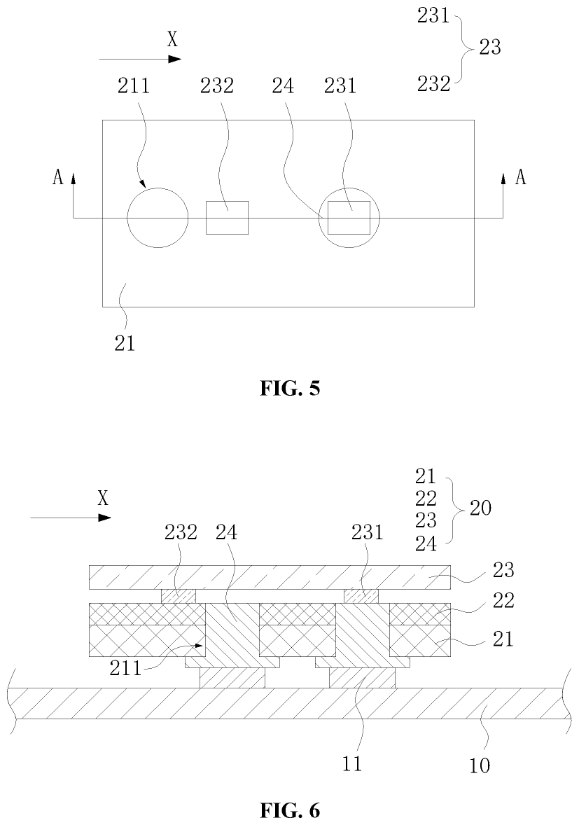

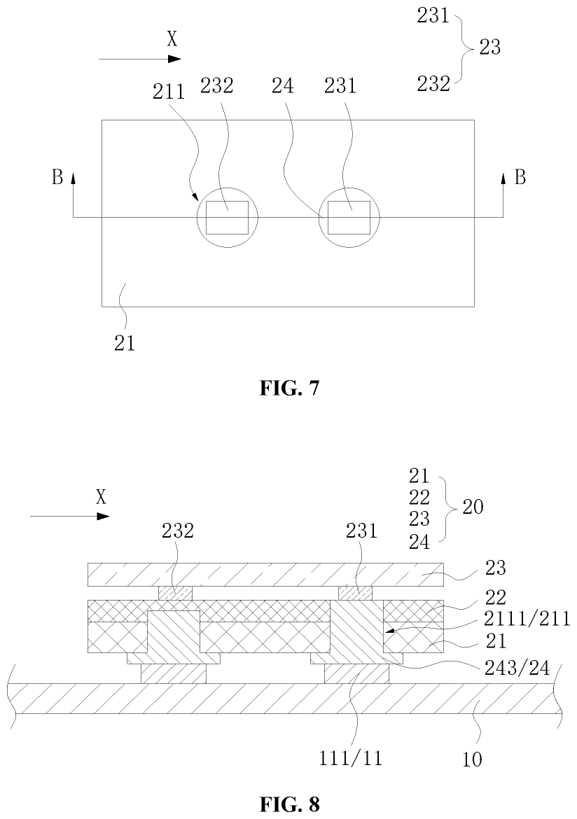

FIG. 5 is a sectional view illustrating the structure of another display panel according to some embodiments of the present application. FIG. 6 is a sectional view illustrating the structure of another display panel according to some embodiments of the present application. FIG. 7 is a top view illustrating the structure of another display panel according to some embodiments of the present application. FIG. 8 is a sectional view taken along B-B of FIG. 7.

As shown in FIGS. 5 to 8, in some optional embodiments, the light-emitting chip 23 includes a first electrode 231 and a second electrode 232. At least one of the first electrode 231 or the second electrode 232 at least partially overlaps the hole structure 211 in a direction perpendicular to the plane where the second substrate 21 is located.

In embodiments of the present application, the preceding arrangement shortens the connection line between the light-emitting chip 23 and the first substrate 10, reduces the current area in the drive assembly 22, and thus reduces the preparation cost of the light-emitting assembly 20.

Exemplarily, the first electrode 231 may be a negative electrode, and the second electrode 232 may be a positive electrode. It is to be noted that as shown in FIG. 6, when the second electrode 232 is a positive electrode, the second electrode 232 at least partially overlaps the hole structure 211 in the direction perpendicular to the plane where the second substrate 21 is located. The second electrode 232 is insulated from the connection portion 24 in the hole structure 211 and is connected to the connection portion 24 in the hole structure 211 through the driver circuit in the drive assembly 22.

In some examples, as shown in FIGS. 5 and 6, the first electrode 231 at least partially overlaps the hole structure 211 in the direction perpendicular to the plane where the second substrate 21 is located. In some other examples, as shown in FIGS. 7 and 8, the second electrode 232 at least partially overlaps the hole structure 211 in the direction perpendicular to the plane where the second substrate 21 is located. In some other examples, the first electrode 231 and the second electrode 232 each at least partially overlap the hole structure 211 in the direction perpendicular to the plane where the second substrate 21 is located. The first electrode 231 is taken for example. The first electrode 231 may overlap the hole structure 211 in the direction perpendicular to the plane where the second substrate 21 is located. Alternatively, an orthographic projection of the first electrode 231 in the direction perpendicular to the plane where the second substrate 21 is located is within an orthographic projection of the hole structure 211 in the direction perpendicular to the plane where the second substrate 21 is located. Alternatively, the orthographic projection of the hole structure 211 in the direction perpendicular to the plane where the second substrate 21 is located is within the orthographic projection of the first electrode 231 in the direction perpendicular to the plane where the second substrate 21 is located. Alternatively, the orthographic projection of the hole structure 211 in the direction perpendicular to the plane where the second substrate 21 is located overlaps the orthographic projection of the first electrode 231 in the direction perpendicular to the plane where the second substrate 21 is located.

As shown in FIG. 8, in some optional embodiments, the connection portions 24 includes a first connection portion 243. The first connection portion 243 corresponds to a first hole structure 2111. The first electrode 231 overlaps the first hole structure 2111 in the direction perpendicular to the plane where the second substrate 21 is located. The first electrode 231 is electrically connected through the first connection portion 243 to a first signal line 111 on a substrate.

In embodiments of the present application, the preceding arrangement simplifies the circuit disposed in the drive assembly 22 and connected to the first electrode 231, thereby simplifying the overall circuit structure of the drive assembly 22 and reducing the preparation cost of the drive assembly 22.

In an embodiment, the first connection portion 243 electrically connects the drive assembly 22 to the signal line 11 through the first hole structure 2111.

In an embodiment, the first electrode 231 may be a negative electrode. The first signal line 111 includes a PVEE signal line 11 configured to supply a negative power signal.

It is to be noted that the PVEE mentioned in the present application refers to Pixel VEE. Pixel denotes a pixel. VEE denotes a negative voltage. Therefore, PVEE denotes supplying the negative voltage to the pixel. Each light-emitting assembly 20 is one pixel.

In embodiments of the present application, the first electrode 231 overlaps the first hole structure 2111 in the direction perpendicular to the plane where the second substrate 21 is located. In other words, the first electrode 231 is directly connected through the first connection portion 243 in the first hole structure 2111 to the first signal line 111 on the first substrate 10. It may be unnecessary to dispose a connection circuit of the first electrode 231 in the drive assembly 22, thereby simplifying the overall circuit structure of the drive assembly 22.

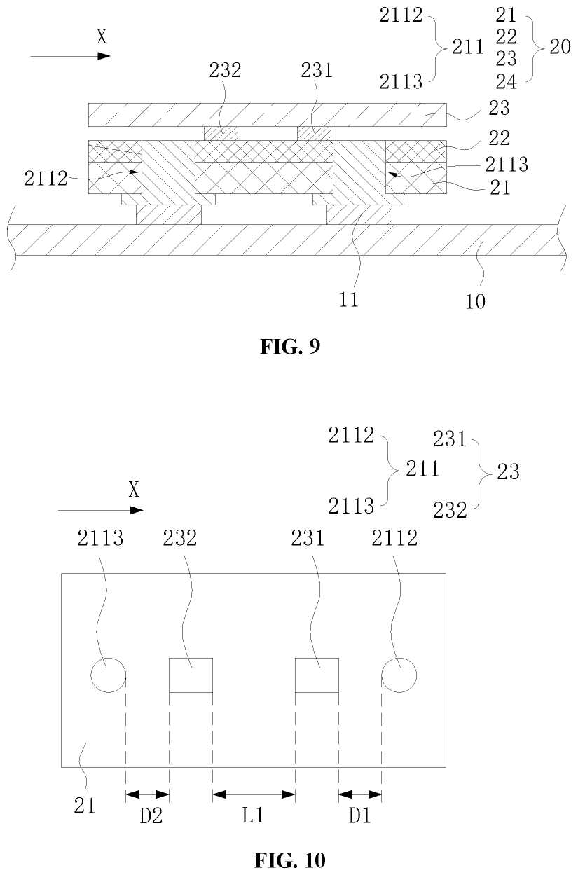

FIG. 9 is a sectional view illustrating the structure of another display panel according to some embodiments of the present application.

As shown in FIG. 9, in some optional embodiments, the light-emitting chip 23 includes the first electrode 231 and the second electrode 232. At least one of the first electrode 231 or the second electrode 232 does not overlap the hole structure 211 in the direction perpendicular to the plane where the second substrate 21 is located.

In embodiments of the present application, the preceding arrangement may enable the connection manner between the first electrode 231 and second electrode 232 that are in the light-emitting chip 23 and the drive assembly 22 to be disposed flexibly according to design requirements, thereby improving the adaptability between the light-emitting chip 23 and the drive assembly 22.

In some examples, the first electrode 231 does not overlap the hole structure 211 in the direction perpendicular to the plane where the second substrate 21 is located. In some other examples, the second electrode 232 does not overlap the hole structure 211 in the direction perpendicular to the plane where the second substrate 21 is located. In some other examples, both the first electrode 231 and the second electrode 232 do not overlap the hole structure 211 in the direction perpendicular to the plane where the second substrate 21 is located. In combination with the preceding content, in some other examples, the first electrode 231 overlaps the hole structure 211 in the direction perpendicular to the plane where the second substrate 21 is located. The second electrode 232 does not overlap the hole structure 211 in the direction perpendicular to the plane where the second substrate 21 is located.

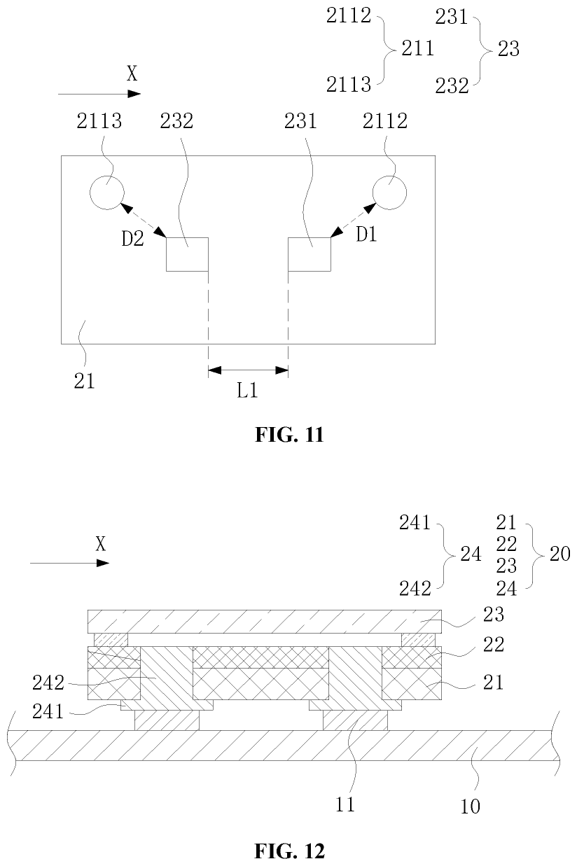

FIG. 10 is a top view illustrating the structure of a light-emitting assembly of a display panel according to some embodiments of the present application. FIG. 11 is a top view illustrating the structure of a light-emitting assembly of another display panel according to some embodiments of the present application.

As shown in FIGS. 9 to 11, in some optional embodiments, the hole structures 211 includes a second hole structure 2112 and a third hole structure 2113. The first electrode 231 and the second electrode 232 are located between the second hole structure 2112 and the third hole structure 2113 in the first direction X.

In embodiments of the present application, the preceding arrangement improves the aesthetics of the hole structures 211 on the second substrate 21 and facilitates the confirmation of mounting positions in the process of connecting the first electrode 231 and the second electrode 232 to the drive assembly 22.

In an embodiment, the second hole structure 2112 and the third hole structure 2113 are disposed on two sides of the second substrate 21 separately in the first direction X. The first electrode 231 and the second electrode 232 are located between the second hole structure 2112 and the third hole structure 2113. The second hole structure 2112 may overlap the third hole structure 2113 in the first direction X. Alternatively, the second hole structure 2112 does not overlap the third hole structure 2113 in the first direction X.

In embodiments of the present application, the first electrode 231 and the second electrode 232 are located between the second hole structure 2112 and the third hole structure 2113 in the first direction X. In other words, as shown in FIG. 10, a connection line of an orthographic projection of the first electrode 231 on the second substrate 21, an orthographic projection of the second electrode 232 on the second substrate 21, an orthographic projection of the second hole structure 2112 on the second substrate 21, and an orthographic projection of the third hole structure 2113 on the second substrate 21 may be disposed in parallel with the first direction X Alternatively, as shown in FIG. 9, an example in which the first electrode 231 faces the second hole structure 2112 and in which the second electrode 232 faces the third hole structure 2113 is taken for description. A connection line of the orthographic projection of the first electrode 231 on the second substrate 21 and the orthographic projection of the second hole structure 2112 on the second substrate 21 intersects the first direction X. A connection line of the orthographic projection of the second electrode 232 on the second substrate 21 and the orthographic projection of the third hole structure 2113 on the second substrate 21 intersects the first direction X. A connection line of the orthographic projection of the first electrode 231 on the second substrate 21 and the orthographic projection of the second electrode 232 on the second substrate 21 is parallel to the first direction X. A connection line of the orthographic projection of the second hole structure 2112 on the second substrate 21 and the orthographic projection of the third hole structure 2113 on the second substrate 21 is parallel to the first direction X.

As shown in FIGS. 10 and 11, in some optional embodiments, in a direction parallel to a plane where the display panel is located, the minimum distance from the first electrode 231 to the second hole structure 2112 is D1, the minimum distance from the second electrode 232 to the third hole structure 2113 is D2, and the minimum distance between the first electrode 231 and the second electrode 232 is L1, D1, D2, and L1 satisfy the relationship below.

$$0 \leq \frac{\vert D 1 - D 2 \vert}{L 1} \leq 1 .$$

In embodiments of the present application, the smaller the ratio of a difference between the distance from the first electrode 231 to the second hole structure 2112 and the distance from the second electrode 232 to the third hole structure 2113 to the distance between he first electrode 231 and the second electrode 232, the smaller the difference between the distance from the first electrode 231 to the second hole structure 2112 and the distance from the second electrode 232 to the third hole structure 2113. In this case, a force generated by the light-emitting chip 23 on the drive assembly 22 is relatively even in the mounting process of aligning the light-emitting chip 23 with the drive assembly 22, reducing the possibility that the circuit in the drive assembly 22 is damaged by the external force. The greater the ratio of the difference between the distance from the first electrode 231 to the second hole structure 2112 and the distance from the second electrode 232 to the third hole structure 2113 to the distance between the first electrode 231 and the second electrode 232, the greater the difference between the distance from the first electrode 231 to the second hole structure 2112 and the distance from the second electrode 232 to the third hole structure 2113, and the greater the mountable range in the mounting process of aligning the light-emitting chip 23 with the drive assembly 22. When the ratio of the difference between the distance from the first electrode 231 to the second hole structure 2112 and the distance from the second electrode 232 to the third hole structure 2113 to the distance between the first electrode 231 and the second electrode 232 is excessively great, the mounting position of the light-emitting chip 23 on the drive assembly 22 faces one of the second hole structure 2112 or the third hole structure 2113 and faces away from the other of the second hole structure 2112 or the third hole structure 2113. As a result, in the mounting process, the external force caused by the light-emitting chip 23 on the drive assembly 22 is close to one side of the drive assembly 22, thereby making the force on one of the hole structures 211 excessively strong and increasing the possibility that the circuit in the drive assembly 22 is damaged by the external force. In embodiments of the present application, the relationship is limited as that 0≤(|D1−D2|)/L1≤1, thereby reducing the possibility that the circuit in the drive assembly 22 is damaged by the external force.

In an embodiment, the value of (|D1−D2|)/L1 includes 0, 0.1, 0.2, 0.3, 0.5, or 1.

FIG. 12 is a sectional view illustrating the structure of another display panel according to some embodiments of the present application.

As shown in FIG. 12, in some optional embodiments, an orthographic projection of the first portion 241 of the connection portion 24 on the second substrate 21 covers an orthographic projection of the second portion 242 on the second substrate 21.

In embodiments of the present application, the preceding arrangement helps increase the sectional area of the first portion 241, thereby reducing the alignment accuracy between the light-emitting assembly 20 and the signal line 11 on the first substrate 10 and reducing the preparation difficulty.

In an embodiment, the shape of the orthographic projection of the first portion 241 of the connection portion 24 on the second substrate 21 includes a circle, a square, or a rectangle. The shape of the orthographic projection of the second portion 242 of the connection portion 24 on the second substrate 21 includes a circle, a square, or a rectangle. By way of example, the orthographic projection of the first portion 241 of the connection portion 24 and the orthographic projection of the second portion 242 of the connection portion 24 on the second substrate 21 are each circular. The center of the first portion 241 and the center of the second portion 242 may coincide with each other. Of course, the center of the first portion 241 and the center of the second portion 242 may not coincide with each other. The first portion 241 and the second portion 242 may be made of the same material. Of course, the first portion 241 and the second portion 242 may also be made of different materials. The first portion 241 and the second portion 242 may be an integral structure. Of course, the first portion 241 and the second portion 242 may be a split structure.

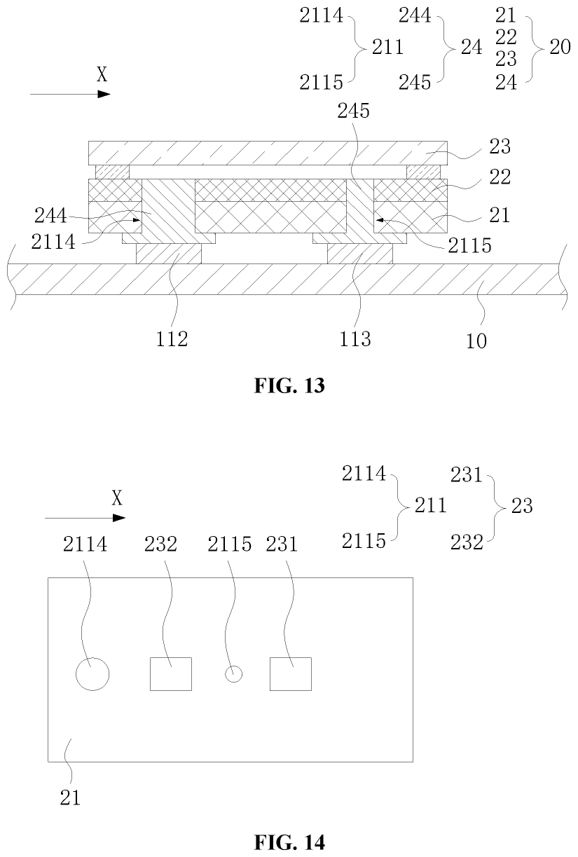

FIG. 13 is a sectional view illustrating the structure of another display panel according to some embodiments of the present application.

As shown in FIG. 13, in some optional embodiments, the signal lines 11 include second signal lines 112 and third signal lines 113. The connection portions 24 include a second connection portion 244 and a third connection portion 245. A second signal line 112 supplies a power signal to the drive assembly 22 through the second connection portion 244. A third signal line 113 supplies a data signal and/or a gating signal to the drive assembly 22 through the third connection portion 245. The second connection portion 244 corresponds to a fourth hole structure 2114. The third connection portion 245 corresponds to a fifth hole structure 2115. The width of the fourth hole structure 2114 in the first direction X is greater than the width of the fifth hole structure 2115 in the first direction X.

In embodiments of the present application, the preceding arrangement differentiates the size of each hole structure 211 according to functionality, thereby reducing a redundant arrangement of the hole structures 211 and thus increasing the arrangement space on the second substrate 21.

In an embodiment, power signals may include positive power signals and negative power signals. The second signal line 112 may include a PVDD signal line 11 and a PVEE signal line 11. The PVDD signal line 11 is configured to supply a positive power signal. The PVEE signal line 11 is configured to supply a negative power signal.

It is to be noted that the PVDD mentioned in the present application refers to Pixel VDD. Pixel denotes a pixel. VDD denotes a positive voltage. Therefore, PVDD denotes supplying the positive voltage to the pixel. Each light-emitting assembly 20 is one pixel.

In an embodiment, the third signal lines 113 includes data signal lines 116 and gating signal lines 117.

In an embodiment, a data signal and a gating signal may output/input a level signal to the drive assembly 22, thereby implementing the control over the drive assembly 22.

In an embodiment, multiple second connection portions 244 may be provided. Different second connection portions 244 are connected to different power signal lines. Multiple third connection portions 245 may be provided. Part of the third connection portions 245 are connected to a data signal line 116, and part of the third connection portions 245 are connected to a gating signal line 117.

FIG. 14 is a top view illustrating the structure of a light-emitting assembly of another display panel according to some embodiments of the present application.

As shown in FIG. 14, in some optional embodiments, the distance from the fourth hole structure 2114 to the center of the second substrate 21 is greater than the distance from the fifth hole structure 2115 to the center of the second substrate 21.

In embodiments of the present application, the preceding arrangement reduces the possibility that the hole structure 211 interferes with the circuit in the drive assembly 22 and reduces the wiring area in which the circuit in the drive assembly 22 is led out and connected to the third connection portion 245.

In embodiments of the present application, the center of the second substrate 21 is a geometric center. The fourth hole structure 2114 is farther from the center of the second substrate 21 compared with the fifth hole structure 2115. The fourth hole structure 2114 may be distributed at a peripheral edge of the second substrate 21. The fifth hole structure 2115 is close to the center of the second substrate 21.

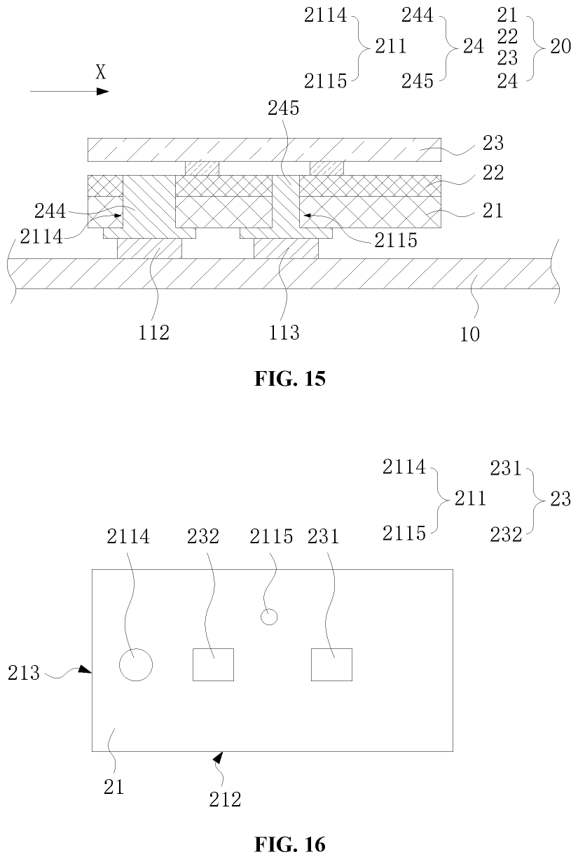

FIG. 15 is a sectional view illustrating the structure of another display panel according to some embodiments of the present application.

As shown in FIGS. 14 and 15, in some optional embodiments, an orthographic projection of the light-emitting chip 23 on the second substrate 21 covers the fifth hole structure 2115.

In embodiments of the present application, the preceding arrangement shorts the

wiring length of a circuit on the third signal line 113—the third connection portion 245—the drive assembly 22, thereby increasing the response speed to the control over the light-emitting chip 23.

In embodiments of the present application, the fifth hole structure 2115 may be located between the first electrode 231 of the light-emitting chip 23 and the second electrode 232 of the light-emitting chip 23. In other words, an orthographic projection of the fifth hole structure 2115 on the second substrate 21 is located between the orthographic projection of the first electrode 231 on the second substrate 21 and the orthographic projection of the second electrode 232 on the second substrate 21. In some other examples, the fifth hole structure 2115 may also be located on a side of the first electrode 231 facing away from the second electrode 232.

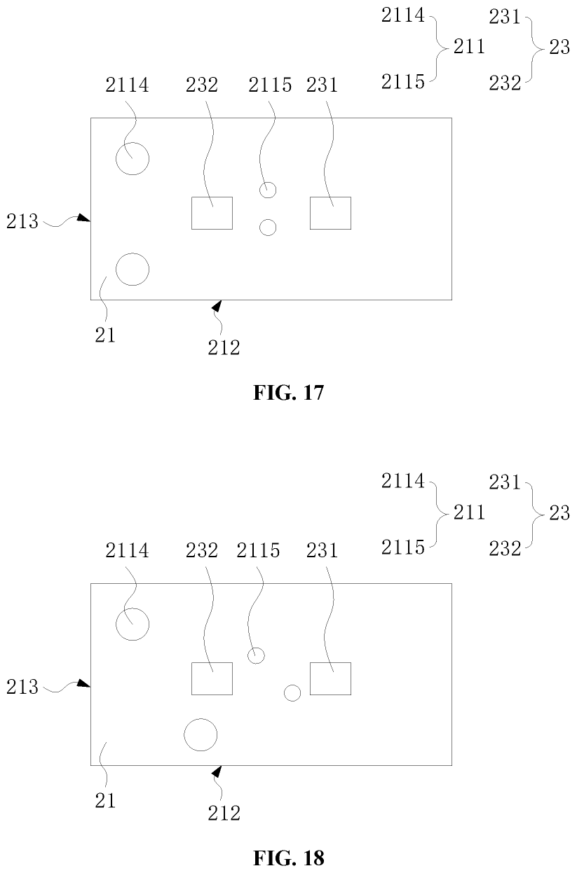

FIG. 16 is a top view illustrating the structure of a light-emitting assembly of another display panel according to some embodiments of the present application. FIG. 17 is a top view illustrating the structure of a light-emitting assembly of another display panel according to some embodiments of the present application. FIG. 18 is a top view illustrating the structure of another display panel according to some embodiments of the present application.

As shown in FIGS. 16 to 18, in some optional embodiments, the second substrate 21 includes first side edges 212 and second side edges 213. A first side edge 212 intersects a second side edge 213. The fourth hole structure 2114 and the fifth hole structure 2115 do not overlap each other in the extension direction of the first side edge 212. The fourth hole structure 2114 and the fifth hole structure 2115 do not overlap each other in the extension direction of the second side edge 213.

In embodiments of the present application, the preceding arrangement enables the fourth hole structure 2114 and the fifth hole structure 2115 to correspond to each other according to the arrangement of the signal lines 11, thereby reducing the space occupied by the pins led out from the signal lines 11 on the first substrate 10 and thus reducing the cost and preparation difficulty.

By way of example, the shape of the second substrate 21 is a cuboid. The first side edge 212 may be a long side of the cuboid. The second side edge 213 may be a wide side of the cuboid. Surfaces defined by the first side edge 212 and the second side edge 213 are a surface facing the first substrate 10 and a surface away from the first substrate 10. Orthographic projections of the fourth hole structure 2114 on the surfaces defined by the first side edge 212 and the second side edge 213 do not overlap orthographic projections of the fifth hole structure 2115 on the surfaces defined by the first side edge 212 and the second side edge 213 in the extension direction of the first side edge 212 and in the extension direction of the second side edge 213.

In an embodiment, as shown in FIG. 17, multiple fourth hole structures 2114 and multiple fifth hole structures 2115 may be provided. The fourth hole structures 2114 do not overlap the fifth hole structures 2115 in the extension direction of the first side edge 212. Moreover, the fourth hole structures 2114 do not overlap the fifth hole structures 2115 in the extension direction of the second side edge 213.

In an embodiment, as shown in FIG. 18, multiple fourth hole structures 2114 and multiple fifth hole structures 2115 may be provided. The fourth hole structures 2114 do not overlap each other in the extension direction of the first side edge 212 and in the extension direction of the second side edge 213. The fifth hole structures 2115 do not overlap each other in the extension direction of the first side edge 212 and in the extension direction of the second side edge 213. Moreover, the fourth hole structures 2114 do not overlap the fifth hole structures 2115 in the extension direction of the first side edge 212. The fourth hole structures 2114 do not overlap the fifth hole structures 2115 in the extension direction of the second side edge 213.

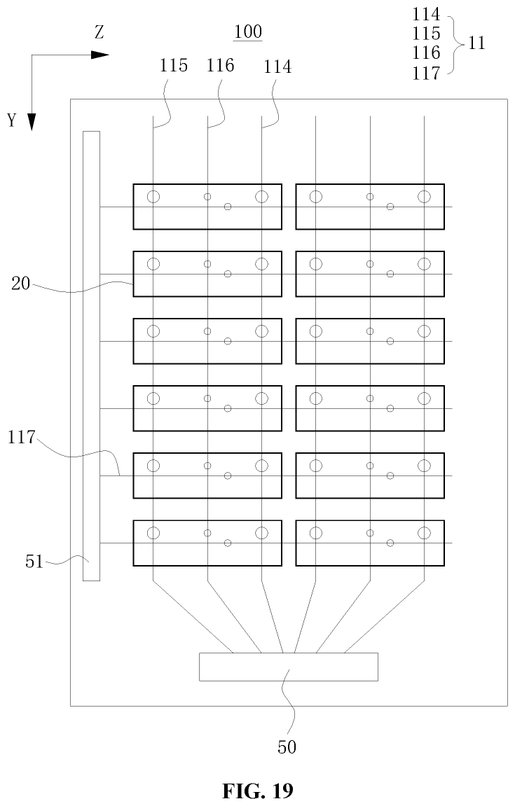

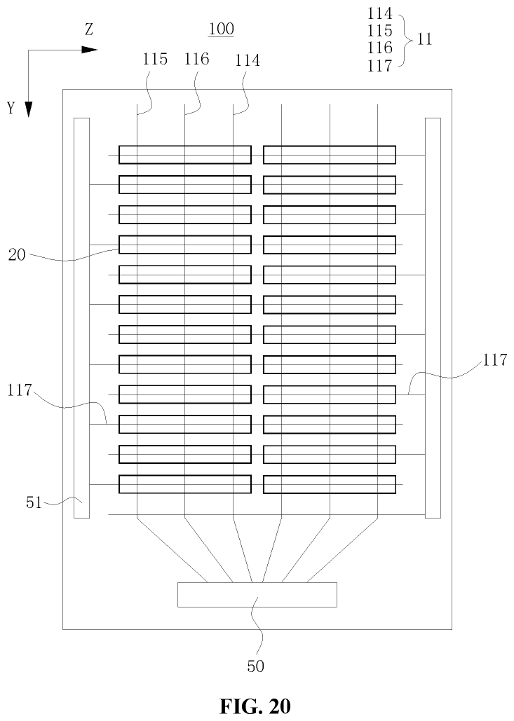

FIG. 19 is a top view illustrating the structure of another display panel according to some embodiments of the present application. FIG. 20 is a top view illustrating the structure of another display panel according to some embodiments of the present application.

As shown in FIGS. 19 and 20, in some optional embodiments, the signal lines 11 include first power signal lines 114, second power signal lines 115, data signal lines 116, and gating signal lines 117. The first power signal lines 114, the second power signal lines 115, and the data signal lines 116 extend in a second direction Y. The gating signal lines 117 extend in a third direction Z. The second direction Y intersects the third direction Z. The second direction Y and the third direction Z are parallel to the plane where the second substrate 21 is located.

In embodiments of the present application, the preceding arrangement enables a power signal, a data signal, and a gating signal to be supplied to the light-emitting assembly 20, implementing the control over the light-emitting assembly 20.

In an embodiment, the first power signal lines 114 include a PVDD power line that can supply a positive voltage to the light-emitting assembly 20. The first power signal lines 114 further include VGH that may be a turn-on voltage of the light-emitting assembly 20.

In an embodiment, the second power signal lines 115 includes a PVEE power line that can supply a negative voltage to the light-emitting assembly 20. The second power signal lines 115 further include VGL that may be a turn-off voltage of the light-emitting assembly 20.

In an embodiment, the data signal lines 116 include a data signal line. The gating signal lines 117 include a clock gating signal line. A data signal line 116 and a gating signal line 117 control the light-emitting assembly 20 together. As shown in FIGS. 19 and 20, the display panel may further include a shift register 51 located on one side of the display panel in the third direction Z or shift registers 51 located on two opposite sides of the display panel in the third direction Z. Multiple gating signal lines 117 are connected to a shift register 51. The shift register 51 may supply a gating signal to the gating signal lines 117. The driver chip in the control unit 50 may also supply a gating signal to the gating signal lines 117. The shift register 51 may also be replaced with a progressive scanning chip. A progressive scanning signal is supplied by the chip directly.

In an embodiment, the second direction Y may be perpendicular to the third direction Z.

In an embodiment, the first power signal lines 114, the second power signal lines 115, the data signal lines 116, and the gating signal lines 117 may be disposed in the same layer. Of course, one or more of the first power signal lines 114, the second power signal lines 115, the data signal lines 116, or the gating signal lines 117 may be disposed in a different layer. Exemplarily, the first power signal lines 114 and the second power signal lines 115 are disposed in the same layer. The data signal lines 116 and the gating signal lines 117 are disposed in the same layer. The first power signal lines 114 are disposed in a different layer from the data signal lines 116. In embodiments of the present application, the layer position of the first power signal lines 114 in the first substrate 10, the layer position of the second power signal lines 115 in the first substrate 10, the layer position of the data signal lines 116 in the first substrate 10, and the layer position of the gating signal lines 117 in the first substrate 10 are not specially limited as long as it guarantees that the first power signal lines 114, the second power signal lines 115, the data signal lines 116, and the gating signal lines 117 have enough wiring space.

In some examples, as shown in FIG. 19, the gating signal lines 117 may extend from one side of the first substrate 10 in the third direction Z toward the other side of the first substrate 10 in the third direction Z. In some other examples, as shown in FIG. 20, the gating signal lines 117 may include two parts. One part of the gating signal lines 117 may extend from one side of the first substrate 10 in the third direction Z toward the other opposite side of the first substrate 10 in the third direction Z. The other part of the gating signal lines 117 may extend from the other side of the first substrate 10 in the third direction Z toward the opposite side of the first substrate 10 in the third direction Z.

In an embodiment, as shown in FIGS. 19 and 20, the first power signal lines 114, the second power signal lines 115, and the data signal lines 116 may be spaced apart in the third direction Z with a first power signal line 114—a data signal line 116— a second power signal line 115 as one repetition unit for wiring in the display panel 100. Of course, in some other examples, the first power signal lines 114, the second power signal lines 115, and the data signal lines 116 may be disposed in other manners as long as it guarantees that the light-emitting assemblies 20 are connected to the first power signal lines 114, the second power signal lines 115, and the data signal lines 116.

In combination with the preceding content, as shown in FIG. 19, the first power signal lines 114, the second power signal lines 115, and the data signal lines 116 extend in the second direction Y. The gating signal lines 117 extend in the third direction Z. In this case, orthographic projections of the four preceding types of signal lines 11 on the first substrate 10 have intersection points. Each light-emitting assembly 20 covers the four preceding types of signal lines 11. In this case, an orthographic projection of part of a fourth hole structure 2114 in each light-emitting assembly 20 on the first substrate 10 overlaps an orthographic projection of a first power signal line 114 on the first substrate 10. An orthographic projection of part of the fourth hole structure 2114 on the first substrate 10 overlaps an orthographic projection of a second power signal line 115 on the first substrate 10. Part of a fifth hole structure 2115 in each light-emitting assembly 20 overlaps a data signal line 116. Part of a fifth hole structure 2115 in each light-emitting assembly 20 overlaps a gating signal line 117.

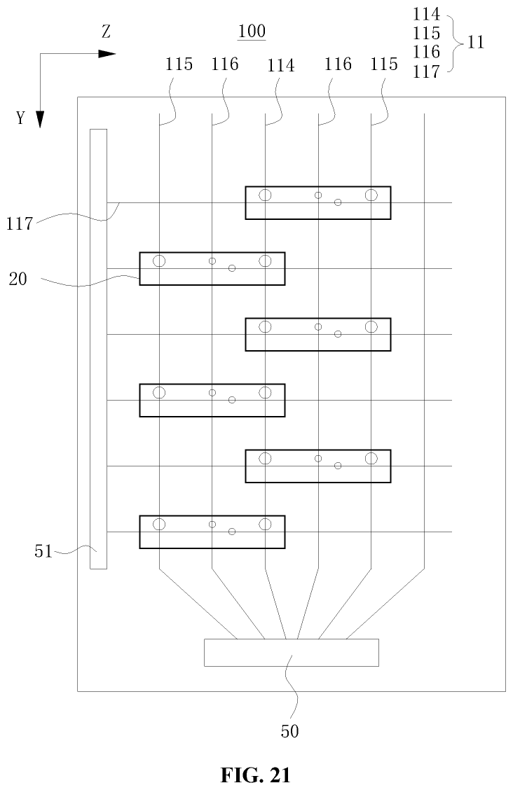

FIG. 21 is a top view illustrating the structure of another display panel according to some embodiments of the present application.

As shown in FIGS. 20 and 21, in some optional embodiments, a data signal line 116 is located between a first power signal line 114 and a second power signal line 115 in the third direction Z.

In embodiments of the present application, the preceding arrangement guarantees that the fourth hole structures 2114 on the second substrate 21 may be distributed at an edge of the second substrate 21 and reduces the wiring space in the center of the second substrate 21 occupied by the fourth hole structures 2114 on the second substrate 21.

By way of example, the light-emitting assemblies 20 are disposed in rows in the second direction Y and disposed in columns in the third direction Z. Two adjacent columns of light-emitting assemblies 20 may share one power signal line 11. Exemplarily, as shown in FIG. 18, two adjacent columns of light-emitting assemblies 20 share a first power signal line 114. Alternatively, two adjacent columns of light-emitting assemblies 20 share a second power signal line 115. Two adjacent columns of light-emitting assemblies 20 may be symmetrical about the shared power signal line 11.

It is to be noted that as shown in FIG. 21, the first power signal lines 114, the second power signal lines 115, and the data signal lines 116 may be spaced apart in the third direction Z with a first power signal line 114—a data signal line 116—a second power signal line 115—a data signal line 116—a first power signal line 114 as one repetition unit for wiring in the display panel 100. Of course, in some other examples, the first power signal lines 114, the second power signal lines 115, and the data signal lines 116 may be disposed in following manners that other different types of signal lines 11 may be symmetrical about the first power signal line 114. The sequence of a first power signal line 114 and a data signal line 116 symmetrical about a second power signal line 115 is not specially limited. Exemplarily, a repetition unit may also include a first power signal line 114—a data signal line 116—a second power signal line 115—a first power signal line 114—a data signal line 116 or a data signal line 116—a first power signal line 114—a second power signal line 115—a first power signal line 114—a data signal line 116.

In combination with the preceding content, as shown in FIGS. 19 and 21, connection portions 24 in the light-emitting assemblies 20 may be adjusted according to different types of signal lines on the first substrate 10. Illustratively, a fourth hole structure 2114 overlapping an orthographic projection of a first power signal line 114 on the first substrate 10 and a fourth hole structure 2114 overlapping an orthographic projection of a second power signal line 115 on the first substrate 10 may be symmetrical about a hole structure of a data signal line.

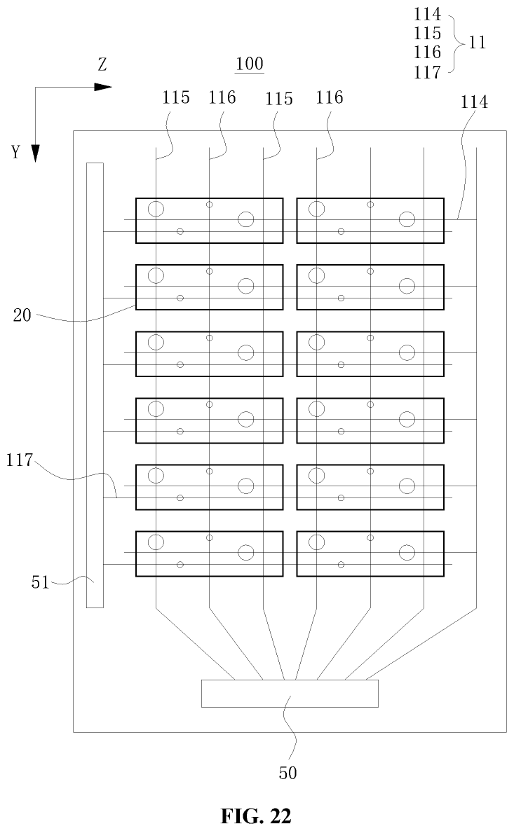

FIG. 22 is a top view illustrating the structure of another display panel according to some embodiments of the present application.

As shown in FIG. 22, in some optional embodiments, the second power signal lines 115 and the data signal lines 116 extend in the second direction Y. The first power signal lines 114 and the gating signal lines 117 extend in the third direction Z. In embodiments of the present application, the preceding arrangement reduces the possibility of interference and crosstalk between different types of signal lines and improves the space utilization of the signal lines on the first substrate 10. In some optional examples, the data signal lines 116 extend in the second direction Y. The first power signal lines 114, the second power signal lines 115, and the gating signal lines 117 extend in the third direction Z.

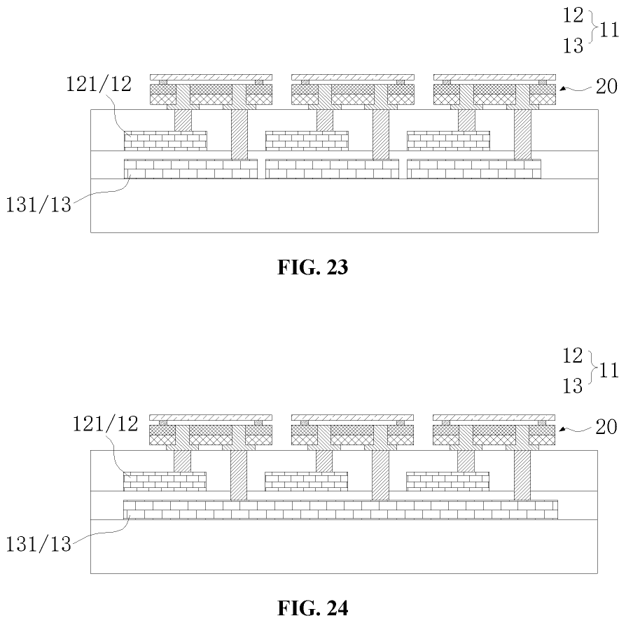

FIG. 23 is a sectional view illustrating the structure of another display panel according to some embodiments of the present application.

As shown in FIG. 23, in some optional embodiments, the first substrate 10 further includes a first conductive layer 12 and a second conductive layer 13 that are insulated from each other. The first conductive layer is located on a side of the second conductive layer facing the light-emitting assemblies 20. The signal lines 11 include power signal lines configured to transmit a fixed high level or a fixed low level and located in the first conductive layer 12. In the optional embodiments, a variable level signal such as a data signal or a gating signal may be disposed in the second conductive layer 13, and a signal line transmitting a fixed level may be disposed in a conductive layer facing the light-emitting assemblies 20, thereby reducing the effect of a non-fixed level signal on a light-emitting signal of the light-emitting assemblies 20.

In embodiments of the present application, the preceding arrangement helps with the accurate control over each light-emitting assembly 20 and increases the response speed to the control over each light-emitting assembly 20. Moreover, the independent control over each light-emitting assembly 20 may reduce the possibility of local brightness unevenness in the display panel 100 and improve the uniformity of the brightness of the display panel 100.

In an embodiment, the first conductive layer 12 may include a plurality of first conductive portions 121. The second conductive layer 13 may include a plurality of second conductive portions 131. Each first conductive portion 121 and each second conductive portion 131 may be electrically connected to one light-emitting assembly 20. Of course, each first conductive portion 121 and each second conductive portion 131 may be electrically connected to multiple light-emitting assemblies 20.

It is to be understood that the first conductive layer 12 in the first substrate 10 and the second conductive layer 13 in the first substrate 10 are intermediate layers in the first substrate 10. The first conductive portions 121 and the second conductive portions 131 need to be connected to the pins on the surface of the first substrate 10 through the through holes. The light-emitting assemblies 20 are connected to the pins on the surface of the first substrate 10.

By way of example, the second conductive layer 13 is located on a side of the first conductive layer 12 facing away from the light-emitting assemblies 20. An orthographic projection of a first conductive portion 121 on the first substrate 10 is located in an orthographic projection of a second conductive portion 131 on the first substrate 10. Part of the second conductive portion 131 not covered by the first conductive portion 121 may be provided with a through hole.

FIG. 24 is a sectional view illustrating the structure of another display panel according to some embodiments of the present application.

As shown in FIG. 24, in some optional embodiments, the first substrate 10 further includes the first conductive layer 12 and the second conductive layer 13 that are insulated from each other. The first conductive layer 12 includes a plurality of first conductive portions 121. The second conductive layer 13 includes a second conductive portion 131. The second conductive portion 131 is a planar electrode. The second conductive layer 13 is located on a side of the first conductive layer 12 facing away from the light-emitting assemblies 20.

In embodiments of the present application, the preceding arrangement simplifies the

arrangement manner of the second conductive layer 13, thereby reducing the preparation difficulty of the second conductive layer 13 and thus simplifying the arrangement manner of the signal lines 11 in the first substrate 10.

In an embodiment, a first conductive portion 121 in the first conductive layer 12 may 10 be an anode. The second conductive portion 131 in the second conductive layer 13 may be a cathode.

In an embodiment, orthographic projections of the first conductive portions 121 on the first substrate 10 are located in an orthographic projection of a second conductive layer 13 on the first substrate 10.

In an embodiment, the arrangement position of each light-emitting assembly 20 on the first substrate 10 may correspond to the arrangement position of each first conductive portion 121 on the first substrate 10, thereby reducing the space occupied by the pins on the first substrate 10.

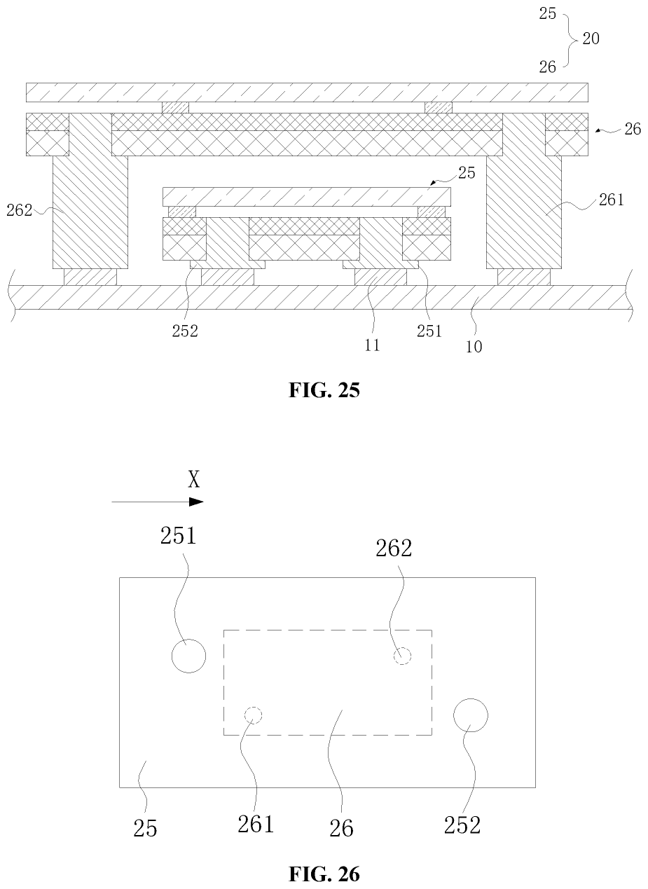

FIG. 25 is a sectional view illustrating the structure of another display panel according to some embodiments of the present application.

As shown in FIG. 25, in some optional embodiments, the light-emitting assemblies 20 include a first light-emitting assembly 25 and a second light-emitting assembly 26. The first light-emitting assembly 25 is located on a side of the second light-emitting assembly 26 facing the first substrate 10. An orthographic projection of the second light-emitting assembly 26 on the first substrate 10 covers an orthographic projection of the first light-emitting assembly 25 on the first substrate 10.

In embodiments of the present application, the preceding arrangement improves the brightness and color richness of the light-emitting assemblies 20. The first light-emitting assembly 25 and the second light-emitting assembly 26 are disposed in the light-emitting assemblies 20 to improve the integration level of the light-emitting assemblies 20, further reducing a non-transparent region occupied by the light-emitting assemblies 20 in the display panel 100.

In an embodiment, the light-emitting color of the first light-emitting assembly 25 and the light-emitting color of the second light-emitting assembly 26 may be the same or, of course, may be different.

By way of example, the light-emitting color of the first light-emitting assembly 25 is different from the light-emitting color of the second light-emitting assembly 26. The first light-emitting assembly 25 and the second light-emitting assembly 26 are stacked. A connection portion 24 of the first light-emitting assembly 25 and a connection portion 24 of the second light-emitting assembly 26 are each connected to signal lines 11 on the first substrate 10. The overall size of the first light-emitting assembly 25 may be smaller than the overall size of the second light-emitting assembly 26.

FIG. 26 is a top view illustrating the structure of a light-emitting assembly of another display panel according to some embodiments of the present application.

As shown in FIGS. 25 to 26, in some optional embodiments, the light-emitting assemblies 20 include connection holes at least penetrating the second substrate 21. The first light-emitting assembly 25 includes a first connection hole 251 and a second connection hole 252. The second light-emitting assembly 26 includes a third connection hole 261 and a fourth connection hole 262. A connection line between the first connection hole 251 and the second connection hole 252 intersects a connection line between the third connection hole 261 and the fourth connection hole 262.

In embodiments of the present application, the preceding arrangement reduces the space occupied by a structure formed by the first light-emitting assembly 25 and the second light-emitting assembly 26 on the first substrate 10 and increases the value of pixels per inch (PPI). Pixel density refers to the number of pixels occupied per inch. The higher the PPI value, the higher the density used by a display screen for displaying an image and the richer the details of the image.

In embodiments of the present application, as shown in FIG. 26, the connection line between the first connection hole 251 and the second connection hole 252 intersects the connection line between the third connection hole 261 and the fourth connection hole 262. In other words, the first connection hole 251 and the second connection hole 252 are not in the same straight line as the third connection hole 261 and the fourth connection hole 262. By way of example, in the first direction X, the first connection hole 251 faces the third connection hole 261, and the second connection hole 252 faces the fourth connection hole 262. For example, the first connection hole 251 and the second connection hole 252 are disposed on two sides of the second substrate 21 in the first direction X. In a direction perpendicular to the first direction X, the first connection hole 251 and the third connection hole 261 are spaced apart, and the second connection hole 252 and the fourth connection hole 262 are spaced apart. In the first direction X, a connection line between the first connection hole 251 and the fourth connection hole 262 may be parallel to the first direction X, and a connection line between the second connection hole 252 and the third connection hole 261 may be parallel to the first direction X. The first connection hole 251, the second connection hole 252, the third connection hole 261, and the fourth connection hole 262 may also be disposed in other manners as long as it guarantees that the first connection hole 251, the second connection hole 252, the third connection hole 261, and the fourth connection hole 262 are not in the same straight line.

In an embodiment, a signal line 11 connected to the first connection hole 251 and a signal line 11 connected to the third connection hole 261 transmit the same signal.

As shown in FIGS. 15 and 25, in some optional embodiments, a sidewall of the drive assembly 22 is coplanar with a sidewall of the light-emitting chip 23, and/or a sidewall of the second substrate 21 is coplanar with the sidewall of the drive assembly 22.

In embodiments of the present application, the preceding arrangement reduces the possibility that a clamp or another component interferes with a light-emitting assembly 20 that has been mounted on the first substrate 10 in the mounting process of the light-emitting assembly 20 and the first substrate 10, thereby improving the preparation yield.

In some examples, the sidewall of the drive assembly 22 is coplanar with the sidewall of the light-emitting chip 23. In some other examples, the sidewall of the second substrate 21 is coplanar with the sidewall of the drive assembly 22. In some other examples, the sidewall of the drive assembly 22, the sidewall of the light-emitting chip 23, and the sidewall of the second substrate 21 are coplanar.

In some optional embodiments, the light-emitting assembly includes a drive wafer and the light-emitting chip. The drive wafer includes the second substrate and the drive assembly.

In embodiments of the present application, the preceding arrangement improves the integration level of the light-emitting assemblies, reduces the preparation process of the light-emitting assemblies, and reduces the preparation cost.

In an embodiment, the drive wafer includes a CMOS wafer. Exemplarily, the second substrate included by the drive wafer may be a base. The material of the second substrate includes silicon (Si). The drive assembly included by the drive wafer may be a CMOS circuit. For example, the drive assembly includes a digital circuit.

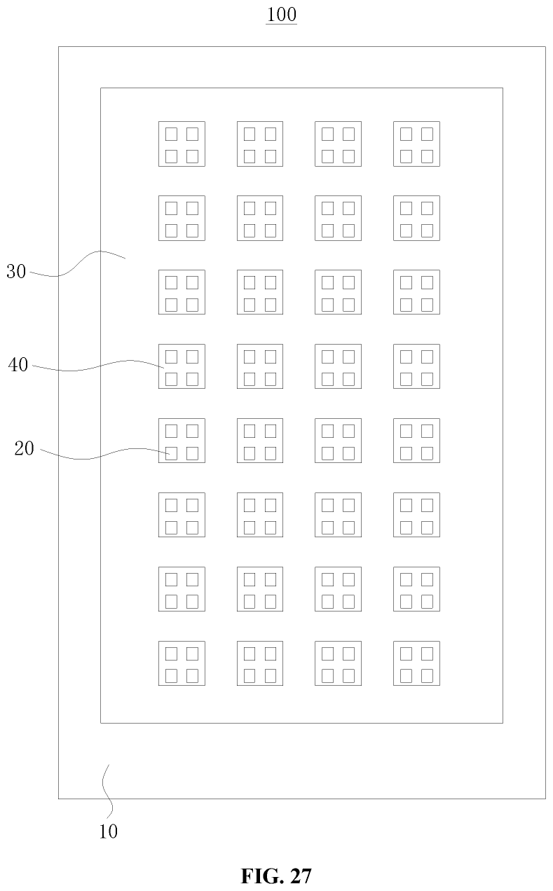

FIG. 27 is a top view illustrating the structure of another display panel according to some embodiments of the present application.

As shown in FIG. 27, in some optional embodiments, a display region of the display panel 100 includes a first region 30 and a second region 40. The transmittance of the first region 30 is greater than the transmittance of the second region 40. The first region 30 at least partially surrounds the second region 40. The second region 40 includes the light-emitting assembly 20.

In embodiments of the present application, the light-emitting assembly 20 is disposed in the second region 40 in the preceding arrangement. The size of the light-emitting assembly 20 is the size of a pixel. Moreover, the driver circuit is integrated in the light-emitting assembly 20, reducing the area occupied by the light-emitting assembly 20 and the driver circuit in the second region, thereby reducing the area of the second region 40, thus increasing the area of the first region 30, and increasing the transmittance of the first region 30.

In an embodiment, multiple second regions 40 may be included in the display region. Each second region 40 is surrounded by the first region 30. Exemplarily, the first region 30 is in a mesh shape. Each second region 40 is located in the mesh or at a node of the mesh.

In an embodiment, multiple light-emitting assemblies 20 may be included in each second region 40. Multiple light-emitting assemblies 20 in each second region 40 may have the same color. Alternatively, multiple light-emitting assemblies 20 in each second region 40 may have different colors. Exemplarily, each second region 40 includes a red light-emitting assembly, a blue light-emitting assembly, and a green light-emitting assembly. Alternatively, each second region 40 includes a red light-emitting assembly, a blue light-emitting assembly, a green light-emitting assembly, and a white light-emitting assembly.

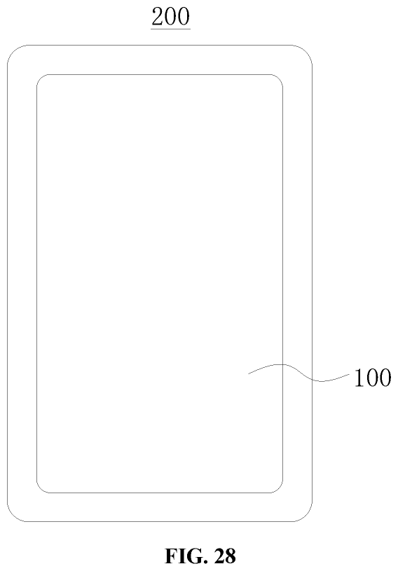

FIG. 28 is a top view illustrating the structure of a display device according to some embodiments of the present application.

In another aspect, as shown in FIG. 28, embodiments of the present application further provide a display device 200 including any preceding display panel 100.

The display device 200 according to embodiments of the present application includes the display panel 100 in any preceding embodiment. Therefore, the display device 200 according to embodiments of the present application has beneficial effects of the display panel 100 in any preceding embodiment, and details about that are not described here again.

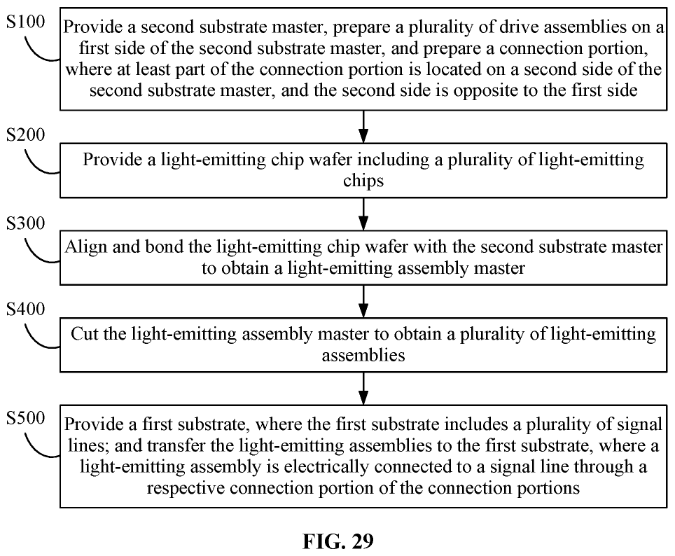

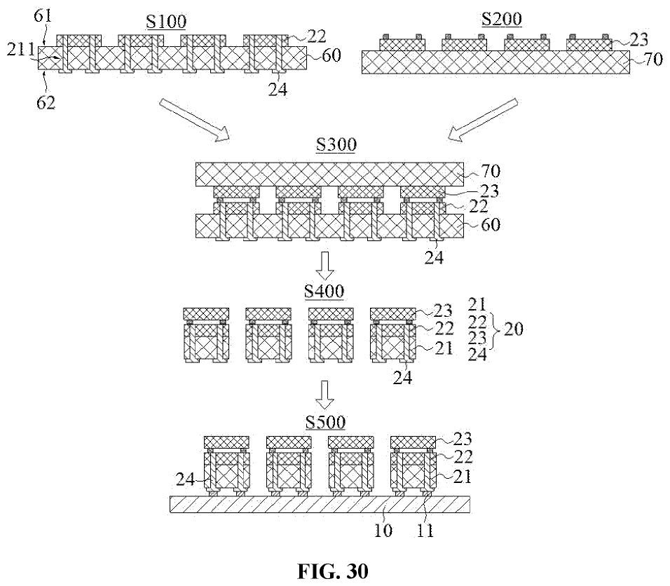

FIG. 29 is a flowchart of a preparation method of a display panel according to an embodiment of the present application. FIG. 30 is a diagram illustrating the process structure of the preparation method of a display panel according to an embodiment of the present application.

In another aspect, as shown in FIGS. 29 and 30, embodiments of the present application further provide a preparation method of a display panel. The preparation method includes the steps below.

In S100, a second substrate master 60 is provided, and a plurality of drive assemblies are prepared on a first side 61 of the second substrate master 60. A connection portion 24 is prepared. At least part of the connection portion 24 is located on a second side 62 of the second substrate master 60. The second side 62 is opposite to the first side 61.

In an embodiment, as shown in FIG. 30, in step S100, the drive assemblies 22 may be formed through manners such as mask bonding or alignment bonding. For example, the drive assemblies 22 include array pixel circuits. An array pixel circuit may be formed through manners such as a mask.

In step S100, a hole structure 211 may be prepared on the second substrate master 60.

The connection portion 24 is formed in the hole structure 211 and on the second side 62 of the second substrate master 60 through deposition. In embodiments of the present application, the connection manner of connecting the connection portion 24 to a drive assembly 22 is not specially limited as long as it guarantees that the connection portion 24 is electrically connected to the drive assembly 22 and that at least part of the connection portion 24 is located on the second side 62 of the second substrate master 60. The drive assembly 22 and the connection portion 24 may be prepared together. Alternatively, the drive assembly 22 and the connection portion 24 may be prepared in sequence. In embodiments of the present application, an example in which the drive assembly 22 is prepared first and then the connection portion 24 is prepared is taken for example.

In S200, a light-emitting chip wafer 70 including a plurality of light-emitting chips 23 is provided.

In an embodiment, as shown in FIG. 30, in step S200, the light-emitting chips 23 include a micro LED or a light-emitting unit formed through QDCF color conversion. Light-emitting chip wafers 70 may include different colors of light-emitting chips. Exemplarily, the light-emitting chip wafers 70 include red light-emitting chips, blue light-emitting chips, and green light-emitting chips. It is to be understood that multiple light-emitting chips in the same color are located on the same light-emitting chip wafer 70.

In S300, the light-emitting chip wafer 70 is aligned with the second substrate master 60 to obtain a light-emitting assembly master.

In an embodiment, as shown in FIG. 30, in step S300, the second substrate master 60 with the drive assemblies 22 is aligned with the light-emitting chip wafer 70, thereby obtaining the light-emitting assembly master with the second substrate master 60, the drive assemblies 22, and the light-emitting chips 23. Different colors of light-emitting chips may form different colors of light-emitting assembly masters. Exemplarily, the light-emitting assembly masters may include a red light-emitting assembly master, a green light-emitting assembly master, and a blue light-emitting assembly master. It is to be understood that the light-emitting chips are separated from the light-emitting chip wafer after alignment so as to facilitate the subsequent preparation process.

In S400, the light-emitting assembly master is cut to obtain a plurality of light-emitting assemblies 20.

In an embodiment, as shown in FIG. 30, in step S400, the light-emitting assemblies 20 formed by cutting may be a plurality of pixel units. Each light-emitting assembly 20 can be controlled independently.

In S500, a first substrate 10 is provided, where the first substrate 10 includes a plurality of signal lines 11; and the light-emitting assemblies 20 are transferred to the first substrate 10, where a light-emitting assembly 20 is electrically connected to a signal line 11 through the connection portion 24.

In an embodiment, as shown in FIG. 30, in step S500, multiple light-emitting assemblies 20 may be transferred together to the first substrate 10 through a massive transfer process. Different colors of light-emitting assemblies are transferred in sequence. Exemplarily, multiple red light-emitting assemblies are transferred together to the first substrate. Multiple blue light-emitting assemblies are transferred together to the first substrate. The first substrate further includes a control unit. The control unit includes a driver chip. The driver chip is prepared on the first substrate through a manner such as transferring or surface mounted technology (SMT). The control unit is connected to the light-emitting assemblies through the signal lines.

Although the present disclosure has been described with reference to preferred embodiments various modifications may be made thereto and components therein may be replaced with equivalents without departing from the scope of the present invention. In particular, the various technical features mentioned in the various embodiments may be combined in any manner as long as there is no structural conflict. The present invention is not limited to the specific embodiments disclosed herein but includes all technical aspects falling within the scope of the claims.

What is claimed is:

1. A display panel, comprising:
a first substrate comprising a plurality of signal lines; and
light-emitting assemblies located on a side of the first substrate, wherein a light-emitting assembly of the light-emitting assemblies comprises a second substrate, a drive assembly, a light-emitting chip, and connection portions; the light-emitting chip is located on a side of the second substrate facing away from the first substrate, the drive assembly and the light-emitting chip are located on a same side of the second substrate, and the drive assembly is configured to drive the light-emitting chip to emit light,
wherein the drive assembly is electrically connected to a respective signal line of the plurality of signal lines through a respective connection portion of the connection portions, and the connection portion is at least partially located on a side of the second substrate facing the first substrate.

2. The display panel according to claim 1, wherein the second substrate comprises a hole structure penetrating the second substrate, a connection portion of the connection portions comprises a first portion located on a side of the second substrate facing the first substrate and a second portion overlapping the hole structure in a first direction, and the first direction is parallel to a plane where the second substrate is located.

3. The display panel according to claim 2, wherein the light-emitting chip comprises a first electrode and a second electrode, and at least one of the first electrode or the second electrode at least partially overlaps the hole structure in a direction perpendicular to the plane where the second substrate is located,
wherein the connection portions comprise a first connection portion, the first connection portion corresponds to a first hole structure, the first electrode overlaps the first hole structure in the direction perpendicular to the plane where the second substrate is located, and the first electrode is electrically connected through the first connection portion to a first signal line on a substrate.

4. The display panel according to claim 2, wherein the light-emitting chip comprises a first electrode and a second electrode, and at least one of the first electrode or the second electrode does not overlap the hole structure in a direction perpendicular to the plane where the second substrate is located.

5. The display panel according to claim 4, wherein the hole structure comprises a second hole structure and a third hole structure, and the first electrode and the second electrode are located between the second hole structure and the third hole structure in the first direction.

6. The display panel according to claim 4, wherein in a direction parallel to a plane where the display panel is located, a minimum distance from the first electrode to the second hole structure is D1, a minimum distance from the second electrode to the third hole structure is D2, and a minimum distance between the first electrode and the second electrode is L1, wherein D1, D2, and L1 satisfies:
$$0 \leq \frac{\vert D 1 - D 2 \vert}{L 1} \leq 1 .$$

7. The display panel according to claim 2, wherein an orthographic projection of the first portion of the connection portion on the second substrate covers an orthographic projection of the second portion on the second substrate.

8. The display panel according to claim 2, wherein the plurality of signal lines comprise a second signal line and a third signal line, the connection portions comprises a second connection portion and a third connection portion, the second signal line supplies a power signal to the drive assembly through the second connection portion, and the third signal line supplies at least one of a data signal or a gating signal to the drive assembly through the third connection portion, wherein the second connection portion corresponds to a fourth hole structure, the third connection portion corresponds to a fifth hole structure, and a width of the fourth hole structure in the first direction is greater than a width of the fifth hole structure in the first direction,

9. The display panel according to claim 8, wherein a distance from the fourth hole structure to a center of the second substrate is greater than a distance from the fifth hole structure to the center of the second substrate, or
wherein an orthographic projection of the light-emitting chip on the second substrate covers the fifth hole structure.

10. The display panel according to claim 8, wherein the second substrate comprises a first side edge and a second side edge, the first side edge intersects the second side edge, the fourth hole structure and the fifth hole structure do not overlap each other in an extension direction of the first side edge, and the fourth hole structure and the fifth hole structure do not overlap each other in an extension direction of the second side edge.

11. The display panel according to claim 2, wherein the plurality of signal lines comprise a first power signal line, a second power signal line, a data signal line, and a gating signal line; the first power signal line, the second power signal line, and the data signal line extend in a second direction; the gating signal line extends in a third direction; the second direction intersects the third direction; and the second direction and the third direction are parallel to the plane where the second substrate is located.

12. The display panel according to claim 11, wherein the data signal line is located between the first power signal line and the second power signal line in the third direction.

13. The display panel according to claim 1, wherein the first substrate further comprises a first conductive layer and a second conductive layer that are insulated from each other, the first conductive layer is located on a side of the second conductive layer facing the light-emitting assemblies, and the plurality of signal lines comprise a power signal line located in the first conductive layer.

14. The display panel according to claim 1, wherein the first substrate further comprises a first conductive layer and a second conductive layer that are insulated from each other, the first conductive layer comprises a plurality of first conductive portions, the second conductive layer comprises a second conductive portion, the second conductive portion is a planar electrode, and the second conductive layer is located on a side of the first conductive layer facing away from the light-emitting assemblies.

15. The display panel according to claim 1, wherein the light-emitting assemblies comprise a first light-emitting assembly and a second light-emitting assembly, the first light-emitting assembly is located on a side of the second light-emitting assembly facing the first substrate, and an orthographic projection of the second light-emitting assembly on the first substrate covers an orthographic projection of the first light-emitting assembly on the first substrate,
wherein the light-emitting assemblies comprise connection holes at least penetrating the second substrate; and
the first light-emitting assembly comprises a first connection hole and a second connection hole, the second light-emitting assembly comprises a third connection hole and a fourth connection hole, and a connection line between the first connection hole and the second connection hole intersects a connection line between the third connection hole and the fourth connection hole.

16. The display panel according to claim 1, wherein the drive assembly satisfies at least one of:
a sidewall of the drive assembly is coplanar with a sidewall of the light-emitting chip, or a sidewall of the second substrate is coplanar with the sidewall of the drive assembly.

17. The display panel according to claim 1, wherein the light-emitting assembly comprises a drive wafer and the light-emitting chip, and the drive wafer comprises the second substrate and the drive assembly.

18. The display panel according to claim 1, wherein a display region of the display panel comprises a first region and a second region, transmittance of the first region is greater than transmittance of the second region, the first region at least partially surrounds the second region, and the second region comprises the light-emitting assembly.

19. A display device, comprising a display panel
wherein the display panel comprises:
a first substrate comprising a plurality of signal lines; and
light-emitting assemblies located on a side of the first substrate, wherein a light-emitting assembly of the light-emitting assemblies comprises a second substrate, a drive assembly, a light-emitting chip, and connection portions; the light-emitting chip is located on a side of the second substrate facing away from the first substrate, the drive assembly and the light-emitting chip are located on a same side of the second substrate, and the drive assembly is configured to drive the light-emitting chip to emit light,
wherein the drive assembly is electrically connected to a respective signal line of the plurality of signal lines through a respective connection portion of the connection portions, and the connection portion is at least partially located on a side of the second substrate facing the first substrate.

20. A preparation method of a display panel, comprising:
providing a second substrate master and preparing a plurality of drive assemblies on a first side of the second substrate master;
preparing connection portions, wherein at least part of the connection portion is located on a second side of the second substrate master, and the second side is opposite to the first side;
providing a light-emitting chip wafer comprising a plurality of light-emitting chips;
aligning and bonding the light-emitting chip wafer with the second substrate master to obtain a light-emitting assembly master;
cutting the light-emitting assembly master to obtain a plurality of light-emitting assemblies; and
providing a first substrate, wherein the first substrate comprises a plurality of signal lines, and transferring the plurality of light-emitting assemblies to the first substrate, wherein one of the plurality of light-emitting assemblies is electrically connected to a respective one of the plurality of signal lines through a respective connection portion of the connection portions.
